(19) United States
(12) Patent Application Publication
(10) Pub. No.: US 2026/0148774 A1
(43) Pub. Date: May 28, 2026

(54) MEMORY DEVICE INCLUDING INTERNAL POWER GENERATING CIRCUIT AND METHOD OF SUPPLYING INTERNAL POWER THEREOF

(71) Applicant: Samsung Electronics Co., Ltd., Suwon-si (KR)

(72) Inventors: June-Hong PARK, Suwon-si (KR); Jinhyeok KIM, Suwon-si (KR); Hyeongdo CHOI, Suwon-si (KR)

(21) Appl. No.: 19/352,273

(22) Filed: Oct. 7, 2025

(30) Foreign Application Priority Data
Nov. 27, 2024 (KR) 10-2024-0172284

(51) Int. Cl. G11C 16/30; G11C 5/14

(52) U.S. Cl. CPC G11C 16/30; G11C 5/147

(57) ABSTRACT

A memory cell array of a memory device includes a plurality of memory cells, an input/output circuit inputting data to the memory cell array or outputting data from the memory cell array, and an internal power generating circuit supplying internal power to the input/output circuit. The internal power generating circuit includes a power driver generating the internal power, a compensation control circuit determining a compensation control current based on a voltage fluctuation of an output node of the power driver, and a voltage compensation circuit compensating for a voltage rise or voltage drop of the output node based on the compensation control current.

### CROSS-REFERENCE TO RELATED APPLICATION(S)

This application claims priority under 35 U.S.C. § 119 to Korean Patent Application No. 10-2024-0172284 filed on Nov. 27, 2024, in the Korean Intellectual Property Office, the entirety of which is incorporated by reference herein.

### BACKGROUND

A semiconductor memory device can be classified as a volatile memory or a non-volatile memory. Read and write speeds of the volatile memory (for example, a DRAM or an SRAM) are fast, but the data stored in the volatile memory disappear when a power is turned off. In contrast, the non-volatile memory may retain data even when the power is turned off. Therefore, the non-volatile memory may be used to store contents that must be preserved regardless of whether power is supplied or not.

### SUMMARY

This disclosure describes a semiconductor memory device including an internal power generating circuit and method of supplying an internal power.

An example of a non-volatile memory is a flash memory. The flash memory can be used as a storage medium for audio and video data in information devices such as a computer and a smartphone. In some examples, high-capacity, high-speed input/output and low-power technologies for the flash memory are used for installation in mobile devices such as the smartphone.

The non-volatile memory can include various internal circuits to input or output data. The non-volatile memory can receive an external power from an external device (for example, a memory controller). In some cases, the external power is adjusted to internal powers determined by each of the internal circuits. The internal powers are repeatedly supplied and cut off to each of the internal circuits, and a voltage drop or voltage rise can occur during this process, which can affect the input/output performance of the non-volatile memory.

Implementations of the present disclosure describe a memory device including a voltage compensation circuit in an internal power generating circuit, monitoring an output voltage of a power driver when supplying internal power, and reducing voltage drop or voltage rise of the output voltage by the voltage compensation circuit.

In some implementations, a memory device including: a memory cell array including a plurality of memory cells; an input/output circuit inputting data to the memory cell array or outputting data from the memory cell array; and an internal power generating circuit supplying internal power to the input/output circuit. The internal power generating circuit includes: a power driver generating the internal power; a compensation control circuit determining a compensation control current based on a voltage fluctuation of an output node of the power driver; and a voltage compensation circuit compensating for a voltage rise (e.g., overshoot) or voltage drop of the output node based on the compensation control current.

In some implementations, a memory device including: a memory cell array including a plurality of memory cells; peripheral circuits supporting inputting data to the memory cell array or outputting data from the memory cell array; and an internal power generating circuit supplying internal power to each of the peripheral circuits. The internal power generating circuit includes: a power driver generating the internal power; a compensation control capacitor connected between an output node and a first node; a compensation control resistor connected between the first node and a second node; a first compensation control transistor including a source connected to a power supply voltage terminal, a gate connected to the first node and a drain connected to the second node; a second compensation control transistor including a source connected to the power supply voltage terminal, a gate connected to the second node and a drain connected to a third node; a first voltage compensation transistor including a drain and a gate connected to the third node, and a source connected to a ground terminal; and a second voltage compensation transistor including a drain connected to the output node, a gate connected to the third node and a source connected to the ground terminal.

In some implementations, a method of supplying internal power in a memory device, the method includes: applying a load current by a power driver; detecting a voltage drop of an output node of the power driver; determining a compensation control current based on the voltage drop; reducing the voltage drop based on the compensation control current; cutting the load current off; detecting a voltage rise (e.g., overshoot) of the output node; re-determining the compensation control current based on the voltage rise; and reducing the voltage rise based on a re-determined compensation control current.

### BRIEF DESCRIPTION OF THE FIGURES

FIG. 1 is a block diagram illustrating a storage device according to an example implementation of the present disclosure.

FIG. 2 is a block diagram illustrating an example implementation of the memory device illustrated in FIG. 1.

FIG. 3 is a circuit diagram illustrating an example implementation of a memory block of the memory cell array illustrated in FIG. 2.

FIG. 4 is a circuit diagram illustrating examples of cell strings selected by a first string selection line among the cell strings of a memory block illustrated in FIG. 3.

FIG. 5 is a circuit diagram illustrating an example of a power driver included in the internal power generating circuit of FIG. 2.

FIG. 6 is a timing diagram illustrating examples of output current and output voltage of the power driver of FIG. 5.

FIG. 7 is a diagram illustrating example operations of the compensation control circuit and the voltage compensation circuit of FIG. 5.

FIG. 8 is a timing diagram illustrating example operations of the compensation control circuit and the voltage compensation circuit when a voltage drop of internal voltage occurs in FIG. 5.

FIG. 9 is a timing diagram illustrating example operations of the compensation control circuit and the voltage compensation circuit when a voltage rise of internal voltage occurs in FIG. 5.

FIG. 10 is a flowchart illustrating an example method of supplying internal power by the internal power generating circuit of FIG. 5.

### DETAILED DESCRIPTION

Below, implementations of the present disclosure will be described in detail and clearly to such an extent that an ordinary one in the art easily implements the inventive concepts.

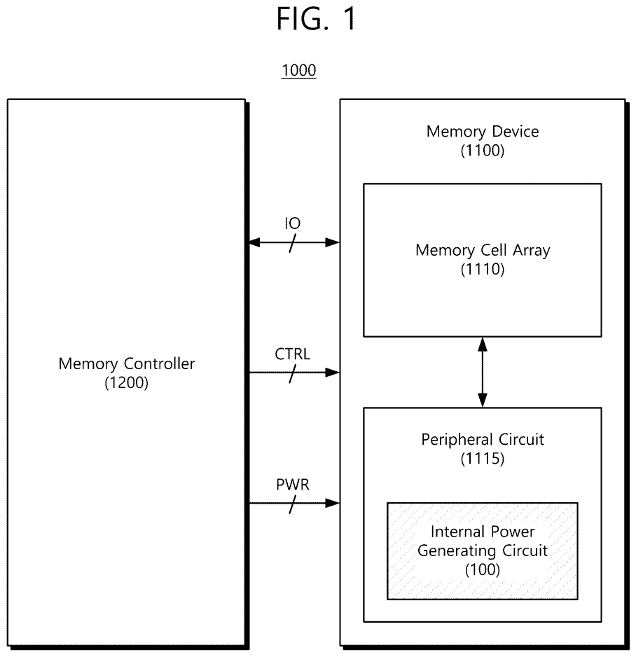

FIG. 1 is a block diagram illustrating a user device according to implementations of the present disclosure. Referring to FIG. 1, a storage device 1000 may include a memory device 1100 and a memory controller 1200. The storage device 1000 of FIG. 1 may be a flash storage device based on the flash memory. For example, the storage device 1000 may be an SSD, UFS and/or memory card, etc.

The memory device 1100 may receive input/output signals IO from the memory controller 1200 through input/output lines, receive control signals CTRL through control lines, and receive external supply power PWR through power lines. The storage device 1000 may store data in the memory device 1100 under control of the memory controller 1200.

The memory device 1100 may include a memory cell array 1110 and a peripheral circuit 1115. The memory cell array 1110 may have a planar 2D structure or a vertical 3D structure. The memory cell array may include a plurality of memory cells. Single-bit data or multi-bit data may be stored in each memory cell.

The memory cell array 1110 may be located (for example, disposed) next to or above the peripheral circuit 1115 in terms of the design layout structure. A structure in which the memory cell array 1110 is positioned above the peripheral circuit 1115 may be referred to as a cell on peripheral (COP) structure. The memory cell array 1110 may be manufactured as a chip, separate from the peripheral circuit 1115. An upper chip including the memory cell array 1110 and a lower chip including the peripheral circuit 1115 may be connected to each other by a bonding method. This structure may be referred to as a chip to chip (C2C) structure.

The peripheral circuit 1115 may include analog circuits and/or digital circuits to store data in the memory cell array 1110 or read data stored in the memory cell array 1110. The peripheral circuit 1115 may receive the external supply power PWR through the power lines and generate internal powers of various levels based on the external supply power PWR.

The peripheral circuit 1115 may receive commands, addresses and/or data from the memory controller 1200 through input/output lines. The peripheral circuit 1115 may store data in the memory cell array 1110 according to the control signals CTRL. Alternatively or additionally, the peripheral circuit 1115 may read data stored in the memory cell array 1110 and provide the read data to the memory controller 1200 according to the control signals CTRL.

The peripheral circuit 1115 may include an internal power generating circuit 100 generating internal powers of various levels based on the external supply power PWR. For example, the internal power generating circuit 100 may generate standby power and active power. The internal power generating circuit 100 may supply internal powers to each part of the memory cell array 1110 and the peripheral circuit 1115.

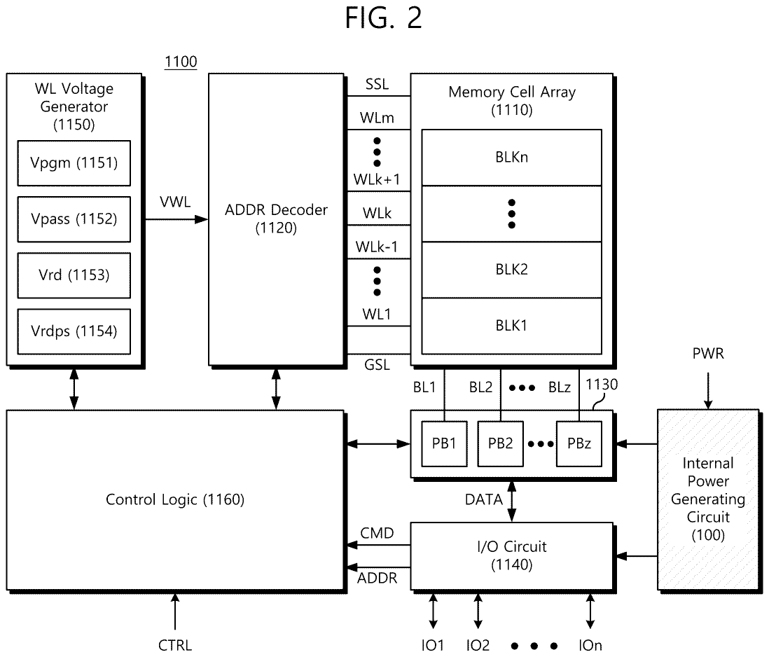

FIG. 2 is a block diagram illustrating an implementation of the memory device illustrated in FIG. 1. Referring to FIG. 2, the memory device 1100 may include a memory cell array 1110 and a peripheral circuit (for example, the peripheral circuit 1115 of FIG. 1). The peripheral circuit may include an address decoder 1120, a page buffer circuit 1130, an input/output circuit 1140, a word line voltage generator 1150 and/or control logic 1160.

The memory cell array 1110 may include a plurality of memory blocks BLK1 to BLKn. Each memory block may be configured to include a plurality of pages. Each page may include a plurality of memory cells. Each memory cell may store multi-bit data (for example, two or more bits). Each memory block may correspond to an erase unit, and each page may correspond to a read and/or write unit.

The memory cell array 1110 may be formed in a direction perpendicular to a substrate. A gate electrode layer and an insulation layer may be alternately deposited on the substrate. Each memory block (for example, BLK1) may be connected to one or more string selection lines SSL, a plurality of word lines WL1 to WLm, and one or more ground selection lines GSL. WLk is a selected word line sWL and the remaining word lines WL1 to WLk−1 and WLk+1 to WLm are unselected word lines uWL.

The address decoder 1120 may be connected to the memory cell array 1110 through selection lines SSL and GSL and word lines WL1 to WLm. The address decoder 1120 may select a word line during a program or read operation. The address decoder 1120 may receive the word line voltage VWL from the word line voltage generator 1150 and provide a program voltage or read voltage to the selected word line.

The page buffer circuit 1130 may be connected to the memory cell array 1110 through bit lines BL1 to BLz. The page buffer circuit 1130 may temporarily store data to be stored in the memory cell array 1110 or data read from the memory cell array 1110. The page buffer circuit 1130 may include page buffers PB1 to PBz connected to respective bit lines. Each page buffer may include a plurality of latches to store or read multi-bit data.

Referring to FIG. 1, the input/output circuit 1140 may be internally connected to the page buffer circuit 1130 through data lines and externally connected to the memory controller 1200 through the input/output lines IO1 to IOn. The input/output circuit 1140 may receive program data from the memory controller 1200 during a program operation. Also, the input/output circuit 1140 may provide data read from the memory cell array 1110 to the memory controller 1200 during a read operation.

The word line voltage generator 1150 may receive internal power from the control logic 1160 and generate a word line voltage VWL to read or write data. The word line voltage VWL may be provided to a selected word line sWL or unselected word lines uWL through the address decoder 1120.

The word line voltage generator 1150 may include a program voltage generator 1151 and a pass voltage generator 1152. The program voltage generator 1151 may generate a program voltage Vpgm provided to the selected word line sWL during a program operation. The pass voltage generator 1152 may generate a pass voltage Vpass provided to the selected word line sWL and the unselected word lines uWL.

The word line voltage generator 1150 may include a read voltage generator 1153 and a read pass voltage generator 1154. The read voltage generator 1153 may generate a select read voltage Vrd provided to the select word line sWL during a read operation. The read pass voltage generator 1154 may generate a read pass voltage Vrdps provided to unselected word lines uWL. The read pass voltage Vrdps may be a voltage sufficient to turn on memory cells connected to the unselected word lines uWL during a read operation.

The control logic 1160 may control operations such as read, write and erase of the memory device 1100 using commands CMD, addresses ADDR and control signals CTRL provided from the memory controller 1200. The addresses ADDR may include a block selection address for selecting one memory block, a row address for selecting one page and a column address for selecting one memory cell.

An internal power generating circuit 100 may generate internal powers of various levels based on the external power PWR. In some implementations, the internal power generating circuit 100 supplies power for the page buffer circuit 1130 and/or the input/output circuit 1140 during a data input/output operation. The internal power generating circuit 100 may supply power at different levels for each of the remaining circuits. The remaining circuits can include, e.g., the memory cell array 1110, the address decoder 1120, the word line voltage generator 1150, and/or the control logic 1160.

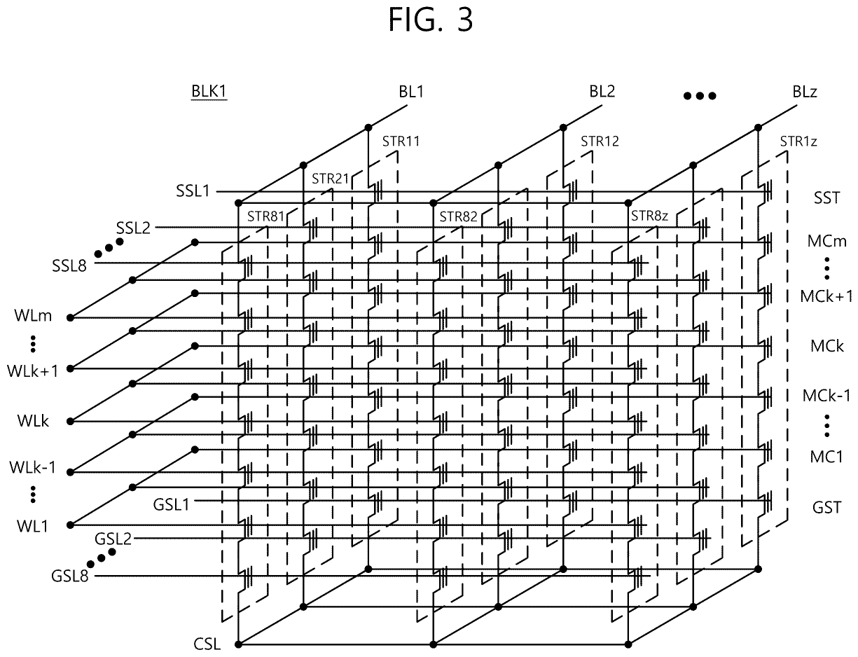

FIG. 3 is a circuit diagram illustrating an implementation of a memory block BLK1 of the memory cell array, as shown in FIG. 2. Referring to FIG. 3, in the memory block BLK1, a plurality of cell strings STR11 to STR8z may be formed between the bit lines BL1 to BLz and a common source line CSL. Each cell string includes a string selection transistor SST, a plurality of memory cells MC1 to MCm and a ground selection transistor GST.

The string selection transistors SST may be connected to string selection lines SSL1 to SSL8. The ground selection transistors GST may be connected to ground selection lines GSL1 to GSL8. The string selection transistors SST may be connected to the bit lines BL1 to BLz and the ground selection transistors GST may be connected to the common source line CSL.

The first to mth word lines WL1 to WLm may be connected to the plurality of memory cells MC1 to MCm in a row direction. The first to zth bit lines BL1 to BLz may be connected to the plurality of memory cells MC1 to MCm in a column direction.

The first word line WL1 may be placed above the first to eighth ground selection lines GSL1 to GSL8. The first memory cells MC1 that are placed at the same height from the substrate may be connected to the first word line WL1. The mth word line WLm may be placed below the first to eighth string selection lines SSL1 to SSL8. The mth memory cells MCm that are placed at the same height from the substrate may be connected to the mth word line WLm. In a similar manner, the second to m-1th memory cells MC2 to MCm-1 that are placed at the same heights from the substrate may be respectively connected with the second to m-1th word lines WL2 to WLm-1.

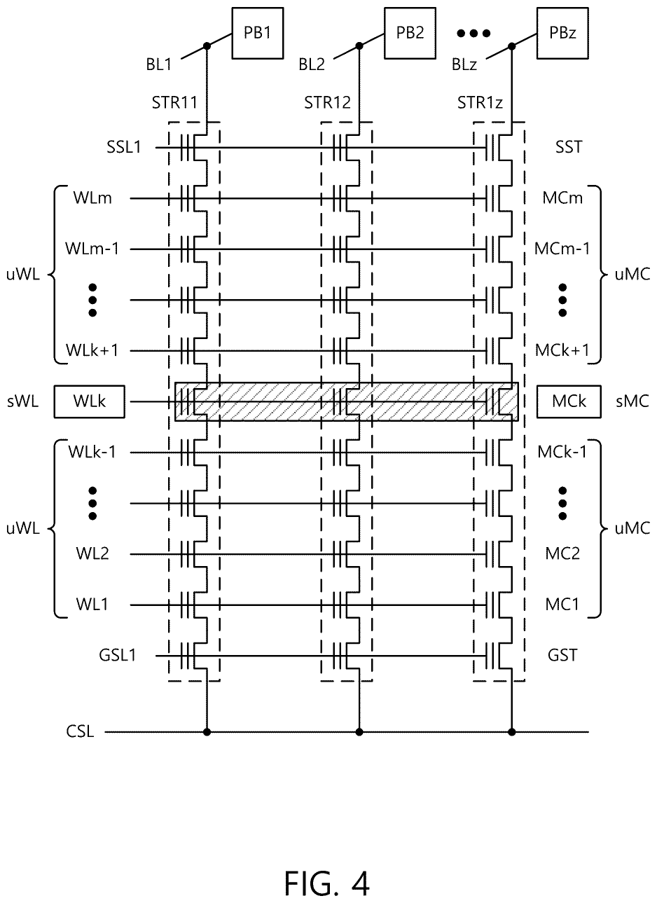

FIG. 4 is a circuit diagram illustrating cell strings selected by the first string selection line SSL1 among the cell strings of the memory block BLK1 illustrated in FIG. 3.

The 11th to 1zth cell strings STR11 to STR1z may be selected by the first string selection line SSL1. The 11th to 1zth cell strings STR11 to STR1z may be connected to the first to zth bit lines BL1 to BLz, respectively. First to zth page buffers PB1 to PBz may be connected to the first to zth bit lines BL1 to BLz, respectively.

The 11th cell string STR11 may be connected to the first bit line BL1 and the common source line CSL. The 11th cell string STR11 may include string selection transistors SST selected by the first string selection line SSL1 and first to mth memory cells MC1 to MCm connected to the first to mth word lines WL1 to WLm, and ground selection transistors GST selected by the first ground selection line GSL1. The twelfth cell string STR12 may be connected to the second bit line BL2 and the common source line CSL. The 1z cell string STR1z may be connected to the zth bit line BLz and the common source line CSL.

The first word line WL1 and the mth word line WLm may be edge word lines (edge WL). The second word line WL2 and the m-1th word line WLm-1 may be edge adjacent word lines (edge adjacent WL). The kth word line WLk may be a selection word line sWL. The k−1th word line WLk−1 and the k+1th word line WLk+1 may be adjacent word lines (adjacent WL) located next to the selected word line. When the kth word line WLk is a selected word line sWL, the remaining word lines WL1 to WLk−1 and WLk+1 to WLm may be unselected word lines uWL.

The first memory cells MC1 and the mth memory cells MCm may be edge memory cells (edge MC). The second memory cells MC2 and the m-1th memory cells MCm-1 may be edge adjacent memory cells (edge adjacent MC). The kth memory cells MCk may be selection memory cells sMC. The k−1th memory cells MCk−1 and the k+1th memory cells MCk+1 may be memory cells adjacent to the selected memory cells (hereinafter referred to as adjacent memory cells (adjacent MC)). When the kth memory cells MCk are selected memory cells sMC, the remaining memory cells MC1 to MCk−1 and MCk+1 to MCm may be unselected memory cells uMC.

A set of memory cells selected by one string selection line and connected to one word line may be one page. For example, memory cells selected by the first string selection line SSL1 and connected to the kth word line WLk may constitute one page. Eight pages may be configured in the kth word line WLk. Among the eight pages, the page connected to the first string selection line SSL1 is a selected page, and the pages connected to the second to eighth string selection lines SSL2 to SSL8 are unselected pages.

The first word line WL1 is a first edge word line (Edge1 WL), and the second word line WL2 is a first edge adjacent word line (Edge1 adjacent WL). The mth word line WLm is a second edge word line (Edge2 WL), and the m-1th word line WLm-1 is a second edge adjacent word line (Edge2 adjacent WL). Word lines between the first and second edge adjacent word lines are middle word lines (middle WL). In some implementations, the kth word line WLk (k is one of 3 to m-2) between the second word line WL2 and the m-1th word line WLm-1 is a middle word line (middle WL).

In some implementations, in a read operation, when the second word line WL2 is a selected word line sWL, the remaining word lines may be unselected word lines uWL. The second word line WL2 may be a first edge adjacent word line (Edge1 adjacent WL). The second memory cells MC2 may be selected memory cells sMC, and the remaining memory cells may be unselected memory cells uMC.

Similarly, in some implementations, when the m-1th word line WLm-1 is a selected word line sWL, the remaining word lines may be unselected word lines uWL. The m-1th word line WLm-1 may be a second edge adjacent word line (Edge2 adjacent WL). The m-1th memory cells MCm-1 may be selected memory cells sMC, and the remaining memory cells may be unselected memory cells uMC.

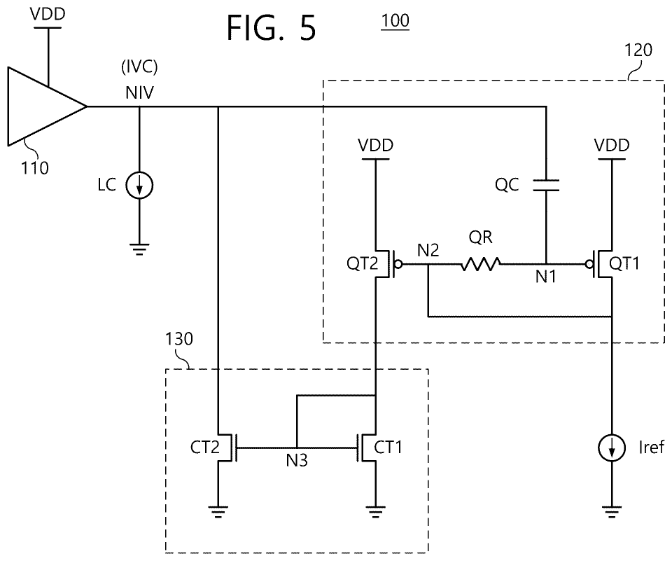

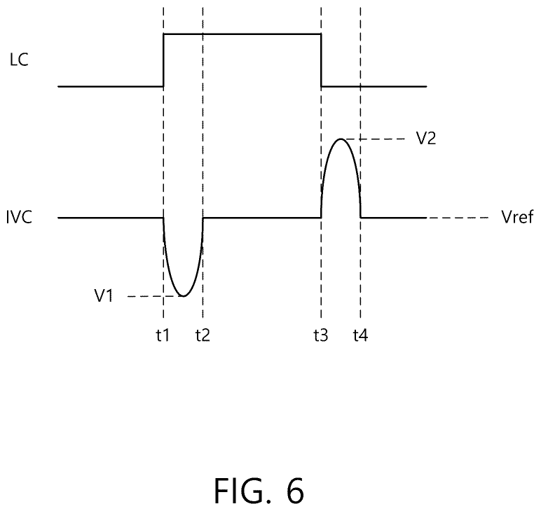

FIG. 5 is a circuit diagram illustrating a power driver included in the internal power generating circuit of FIG. 2. FIG. 6 is a timing diagram illustrating output current and output voltage of the power driver of FIG. 5. Referring to FIG. 5, the internal power generating circuit 100 may include a power driver 110, a compensation control circuit 120 and a voltage compensation circuit 130. Referring to FIGS. 5 and 6, the power driver 110 may generate an internal voltage IVC based on power supply voltage VDD and supply the internal voltage IVC to components of a memory device 1100 (for example, a page buffer circuit 1130 and/or an input/output circuit 1140). The power driver 110 may supply a load current LC at a first time point t1 and cut the load current LC off at a third time point t3.

Between the first time point t1 and a second time point t2, when the power driver 110 supplies the load current LC, the internal voltage IVC may momentarily experience a voltage drop to a first voltage level V1. Between the third time point t3 and a fourth time point t4, when the power driver 110 cuts the load current LC off, the internal voltage IVC may momentarily experience a voltage rise to the second voltage level V2.

If there is no compensation control circuit 120 and voltage compensation circuit 130, when a voltage drop occurs at the first time point t1, operating speed of the memory device 1100 may decrease. In addition, if there is no compensation control circuit 120 and voltage compensation circuit 130, when a voltage rise occurs at the third time point t3, a problem may occur in the reliability of the components of the memory device 1100.

The compensation control circuit 120 may monitor a level change of the internal voltage IVC. The compensation control circuit 120 may transmit a control voltage corresponding to the level change of the internal voltage IVC. The voltage compensation circuit 130 may provide a compensation voltage complementary to the level change of the internal voltage IVC to an internal voltage node NIV based on the control voltage. In some implementations, an internal voltage node NIV may also be referred to as an output node of the power driver.

The compensation control circuit 120 may include a first compensation control transistor QT1, a second compensation control transistor QT2, a compensation control capacitor QC and a compensation control resistor QR. In some implementations, the compensation control circuit 120 may be a quasi-floating gate circuit. In some examples, the first compensation control transistor QT1 and the second compensation control transistor QT2 may be P-type transistors.

A source of the first compensation control transistor QT1 may be connected to the power supply voltage VDD. A gate of the first compensation control transistor QT1 may be connected to a first node N1. A drain of the first compensation control transistor QT1 may be connected to a second node N2. A reference current source Iref may be connected to the second node N2.

A source of the second compensation control transistor QT2 may be connected to the power supply voltage VDD. A gate of the second compensation control transistor QT2 may be connected to the second node N2. A drain of the second compensation control transistor QT2 may be connected to a third node N3.

The compensation control capacitor QC may be connected between the internal voltage node NIV and the first node N1. The compensation control resistor QR may be connected between the first node N1 and the second node N2.

The voltage compensation circuit 130 may include a first voltage compensation transistor CT1 and a second voltage compensation transistor CT2. In some implementations, the first voltage compensation transistor CT1 and the second voltage compensation transistor CT2 are N-type transistors. A drain and a gate of the first voltage compensation transistor CT1 may be connected to the third node N3. A source of the first voltage compensation transistor CT1 may be connected to a ground node. A drain of the second voltage compensation transistor CT2 may be connected to the internal voltage node NIV. A gate of the second voltage compensation transistor CT2 may be connected to the third node N3. A source of the second voltage compensation transistor CT2 may be connected to the ground node.

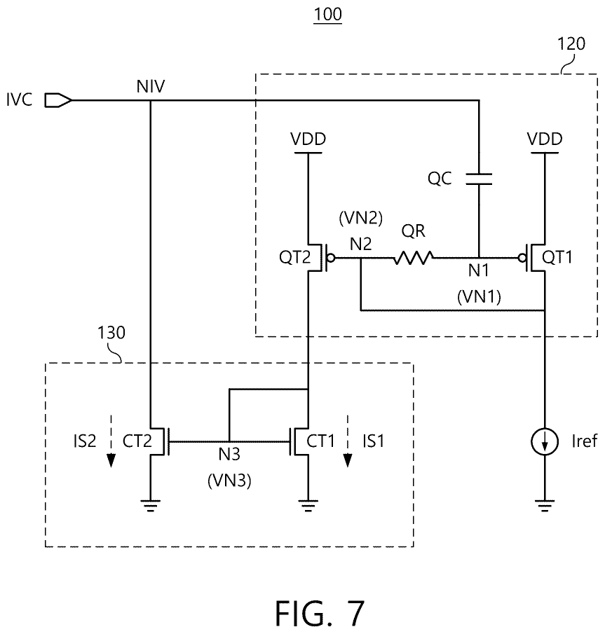

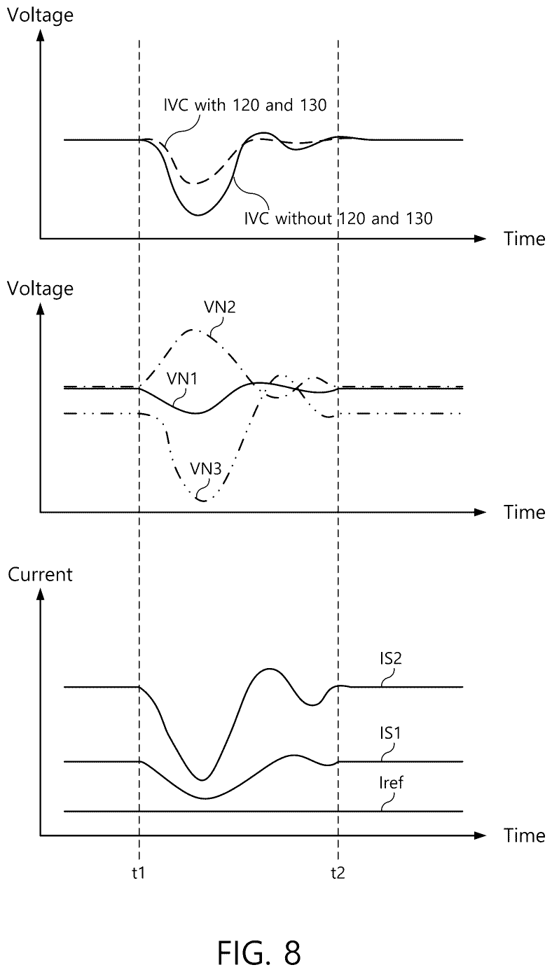

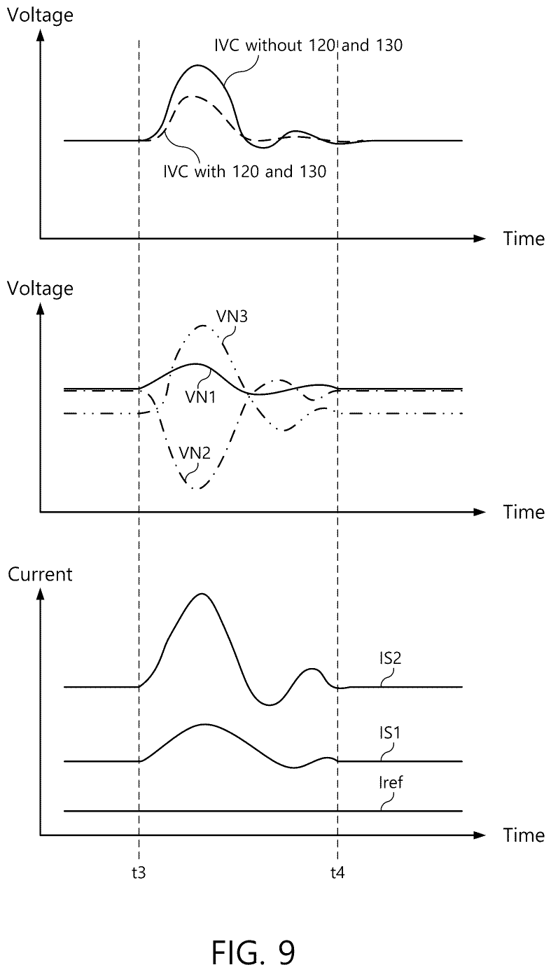

FIG. 7 is a diagram illustrating operations of the compensation control circuit 120 and the voltage compensation circuit 130 of FIG. 5. FIG. 8 is a timing diagram illustrating operations of the compensation control circuit 120 and the voltage compensation circuit 130 when a voltage drop of the internal voltage occurs in FIG. 5. FIG. 9 is a timing diagram illustrating example operations of the compensation control circuit 120 and the voltage compensation circuit 130 when a voltage rise of the internal voltage occurs in FIG. 5.

Referring to FIGS. 7 and 8, a current may flow through the first compensation control transistor QT1, the second compensation control transistor QT2, the first voltage compensation transistor CT1, and the second voltage compensation transistor CT2. In some implementations, a reference current from the reference current source Iref may flow through the first compensation control transistor QT1. A first compensation control current IS1 may flow through the second compensation control transistor QT2 and the first voltage compensation transistor CT1. A second compensation control current IS2 may flow through the second voltage compensation transistor CT2. As an example, the first compensation control current IS1 may be set to be greater than the reference current and the second compensation control current IS2 may be set to be greater than the first compensation control current IS1.

Referring to FIGS. 6, 7 and 8, at the first time point t1, a load current LC may be supplied, causing the internal voltage IVC to decrease. When the internal voltage IVC decreases, a first node voltage VN1 of the first node N1 may decrease at a slower rate than the internal voltage IVC by the compensation control capacitor QC.

Since a constant current flows through the second node N2 from the reference current source Iref, a second node voltage VN2 of the second node N2 may increase at a faster rate than the first node voltage VN1 based on the time constant of the compensation control capacitor QC and the compensation control resistor QR. When the second node voltage VN2 increases, the first compensation control current IS1 may decrease. When the first compensation control current IS1 decreases, a third node voltage VN3 of the third node N3 may decrease complementarily with the second node voltage VN2.

When the third node voltage VN3 decreases, the second compensation control current IS2 may decrease at a faster rate than the first compensation control current IS1, proportionate to capacities of the second compensation control transistor QT2 and the first voltage compensation transistor CT1. When the second compensation control current IS2 decreases, the current supplied to the voltage compensation circuit 130 may be supplemented to the internal voltage node NIV, and a dropping rate of the internal voltage IVC may be reduced.

Referring to FIGS. 6, 7 and 9, at the third time point t3, the load current LC is interrupted, and the internal voltage IVC may rise. When the internal voltage IVC increases, the first node voltage VN1 may increase at a slower rate than the internal voltage IVC through the compensation control capacitor QC.

Since a constant current flows through the second node N2 from the reference current source Iref, the second node voltage VN2 may decrease at a faster rate than the first node voltage VN1 based on the time constant of the compensation control capacitor QC and the compensation control resistor QR. When the second node voltage VN2 decreases, the first compensation control current IS1 may increase. When the first compensation control current IS1 increases, the third node voltage VN3 may increase complementarily with the second node voltage VN2.

When the third node voltage VN3 increases, the second compensation control current IS2 may increase at a faster rate than the first compensation control current IS1, proportionate to capacities of the second compensation control transistor QT2 and the first voltage compensation transistor CT1. When the second compensation control current IS2 increases, the current of the internal voltage node NIV may decrease and a rising rate of the internal voltage IVC may be reduced.

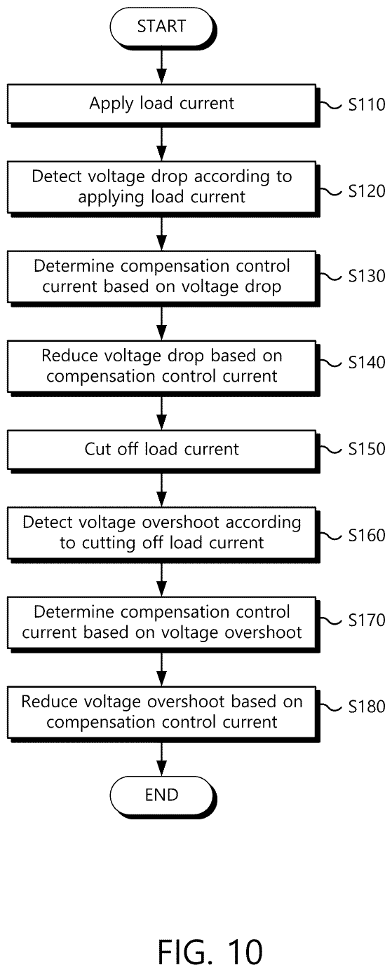

FIG. 10 is a flowchart illustrating an example of a method of supplying internal power by the internal power generating circuit of FIG. 5. Referring to FIGS. 5 to 10, the internal power generating circuit 100 may include a power driver 110, a compensation control circuit 120 and a voltage compensation circuit 130.

In operation S110, the internal power generating circuit 100 may apply a load current LC. In some implementations, the power driver 110 may apply the load current LC to an internal voltage node NIV.

In operation S120, the internal power generating circuit 100 may detect a voltage drop of the internal voltage node NIV of the power driver 110. For example, the compensation control circuit 120 may monitor a voltage level of the internal voltage node NIV. When the voltage level of the internal voltage node NIV decreases, the compensation control circuit 120 may detect the voltage drop. In an example, when the internal voltage IVC decreases, a first node voltage VN1 of a first node N1 may decrease at a slower rate than the internal voltage IVC by the compensation control capacitor QC.

In operation S130, the internal power generating circuit 100 may determine a compensation control current based on the voltage drop of the internal voltage node NIV. For example, since a constant current flows through a second node N2 from the reference current source Iref, a second node voltage VN2 of the second node N2 may increase at a faster rate than the first node voltage VN1 based on a time constant of the compensation control capacitor QC and the compensation control resistor QR. When the second node voltage VN2 increases, the first compensation control current IS1 may decrease.

In operation S140, the internal power generating circuit 100 may reduce the voltage drop of the internal voltage node NIV based on the compensation control current. For example, when the first compensation control current IS1 decreases, a third node voltage VN3 of the third node N3 may decrease. The change in the third node voltage may be complementary to the change in the second node voltage VN2. When the third node voltage VN3 decreases, the second compensation control current IS2 may decrease at a faster rate than the first compensation control current IS1, proportionate to capacities of the second compensation control transistor QT2 and the first voltage compensation transistor CT1. When the second compensation control current IS2 decreases, the current supplied to the voltage compensation circuit 130 may be supplemented to the internal voltage node NIV, and the dropping rate of the internal voltage IVC may be reduced.

In operation S150, the internal power generating circuit 100 may cut the load current LC off. For example, the power driver 110 may interrupt the load current LC.

In operation S160, the internal power generating circuit 100 may detect a voltage increase of the internal voltage node NIV. For example, the compensation control circuit 120 may monitor a voltage level of the internal voltage node NIV. When the voltage level of the internal voltage node NIV increases, the compensation control circuit 120 may detect a voltage rise. In an example, when the internal voltage IVC increases, the first node voltage VN1 may increase at a smaller rate than the internal voltage IVC by the compensation control capacitor QC.

In operation S170, the internal power generating circuit 100 may determine a compensation control current in response to the voltage increase of the internal voltage node NIV. In some implementations, since a constant current flows through the second node N2 from the reference current source Iref, the second node voltage VN2 may decrease at a faster rate than the first node voltage VN1 based on a time constant of the compensation control capacitor QC and the compensation control resistor QR. When the second node voltage VN2 decreases, the first compensation control current IS1 may increase.

In operation S180, the internal power generating circuit 100 may reduce the voltage increase of the internal voltage node NIV based on the compensation control current. In some implementations, when the first compensation control current IS1 increases, the third node voltage VN3 may increase complementarily with the second node voltage VN2. When the third node voltage VN3 increases, the second compensation control current IS2 may increase at a faster rate than the first compensation control current IS1 proportionate to capacities of the second compensation control transistor QT2 and the first voltage compensation transistor CT1. When the second compensation control current IS2 increases, the current of the internal voltage node NIV may decrease, and a rising rate of the internal voltage IVC may be reduced.

According to the present disclosure, it may be possible to reduce a voltage decrease or voltage rise of an output voltage of a power driver in the memory device when internal power is supplied.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a memory cell array comprising a plurality of memory cells;
an input/output circuit configured to input data to the memory cell array and/or output data from the memory cell array; and
an internal power generating circuit configured to supply internal power to the input/output circuit,
wherein the internal power generating circuit comprises
a power driver configured to generate the internal power,
a compensation control circuit configured to determine a compensation control current based on a voltage fluctuation of an output node of the power driver, and
a voltage compensation circuit configured to compensate for a voltage rise or a voltage drop of the output node, based on the compensation control current.

2. The memory device of claim 1, wherein the compensation control circuit is configured to generate the compensation control current based on a reference current and the voltage compensation circuit is configured to receive the compensation control current from the output node.

3. The memory device of claim 2, wherein the compensation control current comprises a first compensation control current and a second compensation control current, wherein the first compensation control current is greater than the reference current, and the second compensation control current is greater than the first compensation control current and supplied from the output node,
wherein the compensation control circuit is configured to reduce the first compensation control current based on a decrease in a voltage level of the output node, and
wherein the voltage compensation circuit is configured to reduce the second compensation control current at a faster rate than the first compensation control current based on the decrease in the voltage level of the output node.

4. The memory device of claim 3, wherein the compensation control circuit is configured to increase the first compensation control current based on an increase in the voltage level of the output node, and
wherein the voltage compensation circuit is configured to increase the second compensation control current at a greater rate than the first compensation control current based on the increase in the voltage level of the output node.

5. The memory device of claim 1, wherein the compensation control circuit comprises:
a compensation control capacitor connected between the output node and a first node;
a compensation control resistor connected between the first node and a second node;
a first compensation control transistor comprising a source connected to a power supply voltage terminal, a gate connected to the first node and a drain connected to the second node; and
a second compensation control transistor comprising a source connected to the power supply voltage terminal, a gate connected to the second node and a drain connected to a third node.

6. The memory device of claim 5, wherein the voltage compensation circuit comprises:
a first voltage compensation transistor comprising a drain and a gate connected to the third node and a source connected to a ground terminal; and
a second voltage compensation transistor comprising a drain connected to the output node, a gate connected to the third node, and a source connected to the ground terminal.

7. The memory device of claim 6, wherein the first compensation control transistor and the second compensation control transistor comprise P-type transistors.

8. The memory device of claim 6, wherein the first voltage compensation transistor and the second voltage compensation transistor comprise N-type transistors.

9. The memory device of claim 6, wherein the second node is connected to a reference current source configured to provide a reference current.

10. The memory device of claim 9, wherein the compensation control current comprises a first compensation control current and a second compensation control current, wherein the first compensation control current is greater than the reference current, and the second compensation control current is greater than the first compensation control current, and wherein the output node is configured to supply the second compensation current,
wherein the first voltage compensation transistor is configured to receive the first compensation control current, and
wherein the second voltage compensation transistor is configured to receive the second compensation control current.

11. A memory device comprising:
a memory cell array including a plurality of memory cells;
a plurality of peripheral circuits configured to support inputting data to the memory cell array and/or outputting data from the memory cell array; and
an internal power generating circuit configured to supply an internal power to each peripheral circuit of the plurality of peripheral circuits,
wherein the internal power generating circuit comprises:
a power driver configured to generate the internal power;
a compensation control capacitor connected between an output node and a first node;
a compensation control resistor connected between the first node and a second node;
a first compensation control transistor comprising a source connected to a power supply voltage terminal, a gate connected to the first node, and a drain connected to the second node;
a second compensation control transistor comprising a source connected to the power supply voltage terminal, a gate connected to the second node, and a drain connected to a third node;
a first voltage compensation transistor comprising a drain and a gate connected to the third node, and a source connected to a ground terminal; and
a second voltage compensation transistor comprising a drain connected to the output node, a gate connected to the third node and a source connected to the ground terminal.

12. The memory device of claim 11, wherein the power driver is configured to produce a voltage at the first node that is proportionate to a capacity of the compensation control capacitor when a voltage of the output node fluctuates.

13. The memory device of claim 11, wherein the power driver is configured to produce a voltage at the second node that is based on a time constant of the compensation control capacitor and the compensation control resistor.

14. The memory device of claim 11,
wherein the first voltage compensation transistor is configured to receive a first compensation control current, and
wherein the second voltage compensation transistor is configured to receive a second compensation control current,
wherein the first compensation control current is greater than a reference current, and the second compensation control current is greater than the first compensation control current and configured to be supplied from the output node.

15. The memory device of claim 14, wherein the second node is connected to a reference current source configured to provide the reference current.

16. A method of supplying internal power in a memory device, the method comprising:
generating, from a power driver, a load current;
detecting a voltage drop of an output node of the power driver;
determining a first compensation control current based on the voltage drop;
reducing the voltage drop based on the first compensation control current;
cutting off the load current;
detecting a voltage rise of the output node;
determining a second compensation control current based on the voltage rise; and
reducing the voltage rise based on the second compensation control current.

17. The method of claim 16, wherein determining the first compensation control current based on the voltage drop comprises reducing, by a compensation control circuit, the first compensation control current based on the voltage drop.

18. The method of claim 17, wherein reducing the voltage drop of the output node comprises reducing, by a voltage compensation circuit, a second compensation control current, which flows to the output node, at a faster rate than a reduction of the first compensation control current.

19. The method of claim 17, wherein determining the second compensation control current based on the voltage increase comprises increasing, by the compensation control circuit, the first compensation control current based on the voltage rise.

20. The method of claim 18, wherein reducing the voltage rise of the output node comprises increasing, by the voltage compensation circuit, the second compensation control current, which flows to the output node, at a faster rate than a rise of the first compensation control current.
